(19) United States
(12) Patent Application Publication
(10) Pub. No.: US 2009/0032056 A1
(43) Pub. Date: Feb. 5, 2009

(54) CONTAMINANT REMOVING METHOD, CONTAMINANT REMOVING MECHANISM, AND VACUUM THIN FILM FORMATION PROCESSING APPARATUS

(75) Inventor: Koji Tsunekawa, Hachioji-shi (JP)

Correspondence Address: FITZPATRICK CELLA HARPER & SCINTO, 30 ROCKEFELLER PLAZA, NEW YORK, NY, 10112, US

(73) Assignee: CANON ANELVA CORPORATION, Kawasaki-shi (JP)

(21) Appl. No.: 12/181,881

(22) Filed: Jul. 29, 2008

(30) Foreign Application Priority Data
Aug. 3, 2007 (JP) 2007-203054

(51) Int. Cl. B08B 7/00; C23C 16/56

(52) U.S. Cl. 134/1.3; 118/722

(57) ABSTRACT

A contaminant removing method of this invention has a step of emitting, in a vacuum, a directional beam to at least one of the lower surface edge and circumferential surface of a substrate to be processed having a thin film formed on its upper surface.

### BACKGROUND OF THE INVENTION

1. Field of the Invention

The present invention relates to, for example, a contaminant removing method and contaminant removing mechanism for removing a contaminant having adhered to the circumferential surface and lower surface of a substrate made of, for example, a semiconductor such as silicon, a metal, glass, ceramics, or plastic when forming a thin film on the substrate in a vacuum.

2. Description of the Related Art

Recently, semiconductor devices and electronic devices are fabricated through the thin film process performed in a vacuum as micropatterning advances. The thin film process fabricates a plurality of devices by forming a thin film on a substrate made of, for example, a semiconductor such as silicon, a metal, glass, ceramics, or plastic. The size of the substrate is more and more increasing in order to increase the yield of chips (the number of chips obtained from one substrate), and silicon wafers having a diameter of 300 mm are beginning to be used instead of those having a diameter of 200 mm. Also, to increase the chip yield, it is effective to use as entirely the substrate surface as possible in addition to increasing the size of the substrate.

As shown in FIG. 12, however, when forming a thin film on the entire surface of a substrate 101, a film 102 adheres to the circumferential surface and lower surface of the substrate 101. If the film 102 sticking to the circumferential surface and lower surface of the substrate 101 peels off and adheres to the upper surface of the substrate 101 in the subsequent step, the device characteristics significantly worsen. As a consequence, the chip yield decreases. For this reason, it is difficult to form a thin film across the entire substrate surface.

To solve this problem, techniques that prevent the adhesion of the film 102 to the circumferential surface and lower surface of the substrate 101 in the thin film formation step have been conventionally proposed. In an example shown in FIG. 13, a mask member 103 is in contact with the edge of the upper surface of the substrate 101. In an example shown in FIG. 14, the mask member 103 is formed to cover the edge of the upper surface of the substrate 101 from above.

Japanese Patent Laid-Open No. 11-176820 has disclosed a film formation apparatus for forming a carbon-based interlayer film by using a high-density plasma source. This film formation apparatus performs a film forming operation by limiting the film formation range so as not to form any carbon film on at least that portion of the edge of a substrate which is not cooled because the substrate is not in contact with a substrate holder. More specifically, this film formation apparatus uses a ring-like member so as not to form any carbon film on the edge of the upper surface of a substrate to be processed mounted on the holder.

Unfortunately, if the mask material shown in FIG. 13 or 14 is used to prevent the adhesion of a film to the circumferential surface and lower surface of a substrate in the thin film formation step, no thin film can be formed near an edge A of the upper surface of the substrate 101 as shown in FIG. 15A. That is, no thin film can be formed across the entire upper surface of the substrate including the edge of the surface. As shown in FIG. 15B, therefore, chips formed on the substrate 101 and having formation regions extending to the edge A of the substrate 101 become defective. This makes it impossible to maximize the chip yield.

Note that there is a known technique that removes fine particles (dust) sticking to a substrate with a cleaning solution, and this technique can also remove a film attached to the circumferential surface and lower surface of a substrate. However, it takes a lot of labor and time to perform a cleaning step after each of a large number of film formation steps is executed. Since the processing cost also significantly increases, this method is not a favorable solution.

It is therefore an object of the present invention to provide a contaminant removing method, contaminant removing mechanism, and vacuum thin film formation processing apparatus capable of removing a film (contaminant) sticking to the lower surface edge and circumferential surface of a substrate to be processed.

### SUMMARY OF THE INVENTION

To achieve the above object, a contaminant removing method of the present invention mainly has the following step.

According to one aspect of the present invention, there is provided a contaminant removing method of removing a contaminant from a substrate to be processed, the method comprising a step of emitting, in a vacuum, a directional beam to at least one of a lower surface edge and circumferential surface of a substrate to be processed having a thin film formed on an upper surface thereof.

Also, to achieve the above object, a contaminant removing mechanism of the present invention has the following arrangement.

According to another aspect of the present invention, there is provided a contaminant removing mechanism for removing a contaminant from a substrate to be processed, the mechanism comprising contaminant removing means for removing a contaminant adhered to at least one of a lower surface edge and circumferential surface of a substrate to be processed having a thin film formed on an upper surface thereof.

The present invention can remove a film (contaminant) sticking to the lower surface edge and circumferential surface of a substrate to be processed.

Further features of the present invention will become apparent from the following description of exemplary embodiments with reference to the attached drawings.

### BRIEF DESCRIPTION OF THE DRAWINGS

FIG. 1 is a view showing an outline of the arrangement of a contaminant removing mechanism and contaminant removing chamber to which the present invention is applicable;

FIGS. 2A and 2B are views showing the positional relationship between a substrate to be processed and the ion gun;

FIGS. 3A and 3B are views showing the states of the adhesion of a film to the lower surface edge and circumferential surface of the substrate to be processed before and after ion beam emission;

FIGS. 4A and 4B are views showing the positional relationship between the substrate to be processed and the ion gun;

FIGS. 5A and 5B are views showing the positional relationship between the substrate to be processed and the ion gun;

FIG. 6 is a view showing the positional relationship between the substrate to be processed and the ion gun;

FIG. 7 is a view showing an outline of the arrangement of a flash memory insulating film formation apparatus as an example of a vacuum thin film formation processing apparatus of the present invention;

FIG. 8 is a view showing an outline of the arrangement of a magnetic random access memory (MRAM) magnetic tunnel junction formation apparatus as an example of the vacuum thin film formation processing apparatus of the present invention;

FIGS. 9A and 9B are views showing the states of the adhesion of a film to the lower surface edge and circumferential surface of the substrate to be processed before and after ion beam emission;

FIG. 10 is a view showing an outline of the arrangement of an apparatus for processing a substrate to be processed on which a patterned photoresist is formed on a magnetic tunnel junction formed in the fourth embodiment, as an example of the vacuum thin film formation processing apparatus of the present invention;

FIG. 11 is a view showing an outline of the arrangement of a phase change memory thin film formation apparatus as an example of the vacuum thin film formation processing apparatus of the present invention;

FIG. 12 is an exemplary view for explaining a thin film formation step of prior art;

FIG. 13 is an exemplary view for explaining a thin film formation step of prior art;

FIG. 14 is an exemplary view for explaining a thin film formation step of prior art; and

FIGS. 15A and 15B are exemplary views for explaining a thin film formation step of prior art.

### DESCRIPTION OF THE EMBODIMENTS

A contaminant removing mechanism according to an embodiment of the present invention has an ion gun (beam emitting means) as a contaminant removing means for removing a thin film (contaminant) sticking to the lower surface edge and circumferential surface of a substrate to be processed on the upper surface of which the thin film is formed. The ion gun is installed in a vacuum chamber including a vacuum pump for evacuating the interior. A substrate holder is also installed in the vacuum chamber. The substrate holder holds and fixes the substrate to be processed such that the thin film formation processing surface of the substrate on which the thin film is formed faces up. The substrate is fixed to the substrate holder by electrostatic force. A rotating mechanism can rotate the substrate holder holding the substrate to be processed. Note that the size of the substrate holder is smaller than that of the substrate to be processed so as to expose the lower surface edge of the substrate.

The ion gun is set below the substrate to be processed placed on the substrate holder so that an ion beam impinges upon the lower surface edge and circumferential surface of the substrate. The vacuum degree in the vacuum chamber is preferably such that the pressure is 0.1 Pa or less. An example of the contaminant removing means applicable to the present invention is a beam emitting means for emitting a directional beam such as an ion beam, electron beam, atomic beam, molecular beam, cluster beam (particle beam made up of a plurality of atoms), or laser beam. An ion beam is particularly suitable as the beam emitting means because the beam has a high directivity and can be emitted toward only the lower surface edge and circumferential surface of a substrate.

As the ion species of the ion beam, it is favorable to use an ion of at least one element selected from He, N, O, Ne, Ar, Kr, and Xe. He, Ne, Ar, Kr, and Xe are suitable because they are inert gases and do not react with a thin film formed on a substrate to be processed. That is, it is possible to prevent the ion beam from deteriorating the characteristics of a thin film formed on a substrate to be processed. Note that O is originally inadequate as an ion species to be used because it reacts with a thin film formed on a substrate to be processed. However, if a contaminant attached to the substrate is an organic substance, O has an effect of reacting with the organic substance and cleaning the substrate. Also, if a thin film formed on a substrate to be processed is an oxide, an oxygen ion beam has no adverse influence. This similarly applies to N. That is, if a thin film formed on a substrate to be processed is a nitride, nitrogen ions do not deteriorate the characteristics of the nitride film. In addition, O and N are practical because they are inexpensive.

The beam size of the emitted beam is preferably small so that the beam does not bounce off the substrate holder and the inner walls of the vacuum chamber to contaminate the upper, lower, and circumferential surfaces of a substrate. More specifically, the beam size is preferably 5 mm or less.

A vacuum thin film formation processing apparatus according to an embodiment of the present invention has at least one vacuum chamber (contaminant removing chamber) including the contaminant removing mechanism described above. The vacuum thin film formation processing apparatus further has, as a vacuum processing chamber, at least one of a physical vapor deposition (PVD) chamber, chemical vapor deposition (CVD) chamber, physical etching chamber, chemical etching chamber, substrate heating chamber, substrate cooling chamber, oxidizing chamber, reducing chamber, and ashing chamber. The contaminant removing chamber and at least one vacuum processing chamber are connected via a vacuum transfer chamber. Accordingly, a substrate to be processed is transferred in a vacuum between the contaminant removing chamber and vacuum processing chamber without being exposed to the atmosphere.

In the vacuum thin film formation processing apparatus of this embodiment, the contaminant removing mechanism installed in the contaminant removing chamber can remove a thin film (contaminant) sticking to the lower surface edge and circumferential surface of a substrate to be processed on which the thin film is formed. The step of removing the film (contaminant) adhered to the lower surface edge and circumferential surface of the substrate to be processed can be performed after all thin films are formed or after each film formation step is complete.

As a thin film formation method in the physical vapor deposition (PVD) chamber, it is possible to use, for example, magnetron sputtering, laser abrasion, ion beam sputtering, or ion plating. It is also possible to use, for example, resistance heating deposition, electron beam deposition, or MBE (Molecular Beam Epitaxy).

As a thin film formation method in the chemical vapor deposition (CVD) chamber, it is possible to use, for example, plasma CVD, thermal CVD, optical CVD, Cat (catalyst) CVD, MO (Metal Organic) CVD, or ALD (Atomic Layer Deposition).

As an etching method in the physical etching chamber, it is possible to use ion beam etching (ion milling), reverse sputter etching, or the like.

As an etching method in the chemical etching chamber, reactive ion etching (RIE) or the like can be used.

As an oxidizing method in the oxidizing chamber, it is possible to use, for example, radical oxidation, plasma oxidation, natural oxidation, or ion beam oxidation.

In the ashing chamber, a photoresist used as a mask in the etching process is exposed to an oxygen plasma ambient or the like and ashed away.

Embodiments of the present invention will be explained below.

### First Embodiment

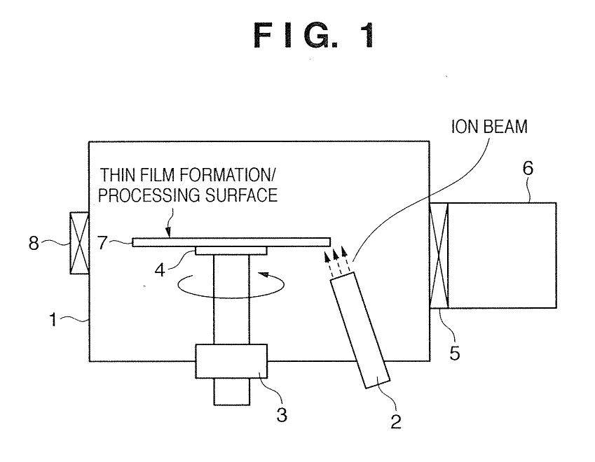

FIG. 1 is a view showing an outline of the arrangement of a contaminant removing mechanism and contaminant removing chamber to which the present invention is applicable.

An ion gun 2 forming the contaminant removing mechanism and an electrostatic force type substrate holder 4 including a substrate rotating mechanism 3 are installed in a vacuum chamber 1 forming the contaminant removing chamber. A vacuum pump 6 is connected to the vacuum chamber 1 via a gate valve 5. A substrate 7 to be processed is loaded into the vacuum chamber 1 through a gate valve 8 formed on the side away from the vacuum pump 6. The vacuum pump 6 sets the vacuum chamber 1 at a desired vacuum degree. In this embodiment, the vacuum degree in the vacuum chamber 1 is 1×10⁻⁵ Pa.

The size of the substrate holder 4 is smaller than that of the substrate 7, and the substrate holder 4 holds a central portion of the substrate 7. Therefore, the circumferential surface and lower surface edge of the substrate 7 held by the substrate holder 4 are exposed without being covered with the substrate holder 4.

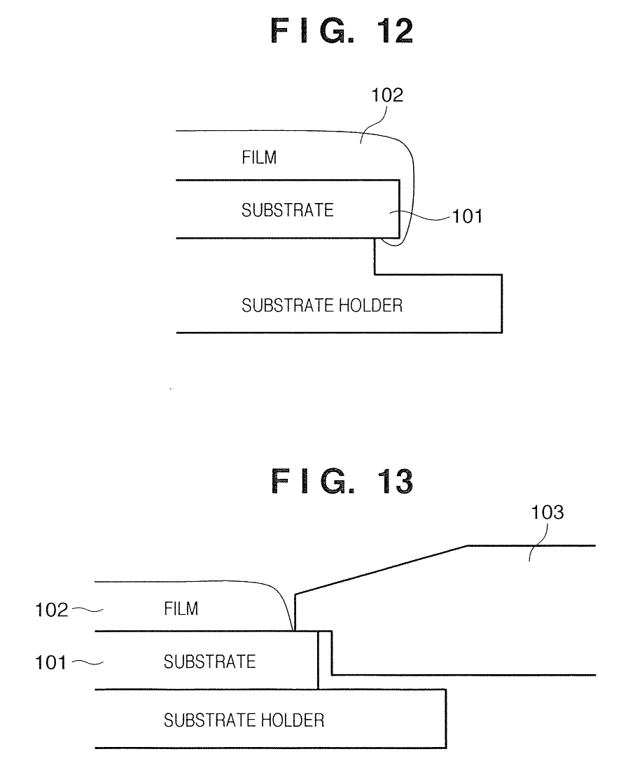

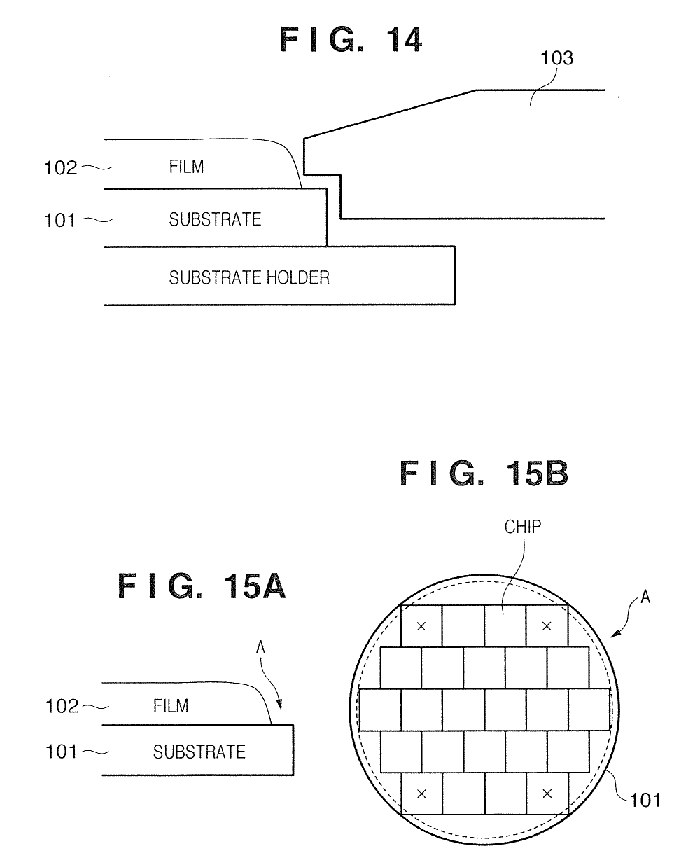

In this embodiment, a silicon wafer having a diameter of 300 mm is used as the substrate 7. A film is sticking not only to the upper surface but also to the circumferential surface and the whole periphery within the range of 2 mm from the edge of the lower surface of the substrate 7 through a thin film formation step (the state shown in FIG. 12). The film has adhered to the circumferential surface and lower surface of the substrate 7 because a substrate holder having a diameter of 296 mm smaller than a wafer size of 300 mm is used in the preceding film formation step. The substrate 7 having the film thus attached is placed on the electrostatic force type substrate holder 4 having a diameter of 100 mm, and fixed on the substrate holder 4 by an electrostatic force. In this state, the substrate rotating mechanism 3 rotates the substrate 7 at a rational speed of 30 rpm. The ion gun 2 emits the ion beam to the edge and circumferential surface of the rotating substrate 7 from its lower surface side. In this embodiment, an ion beam having a beam diameter of 5 mm was used.

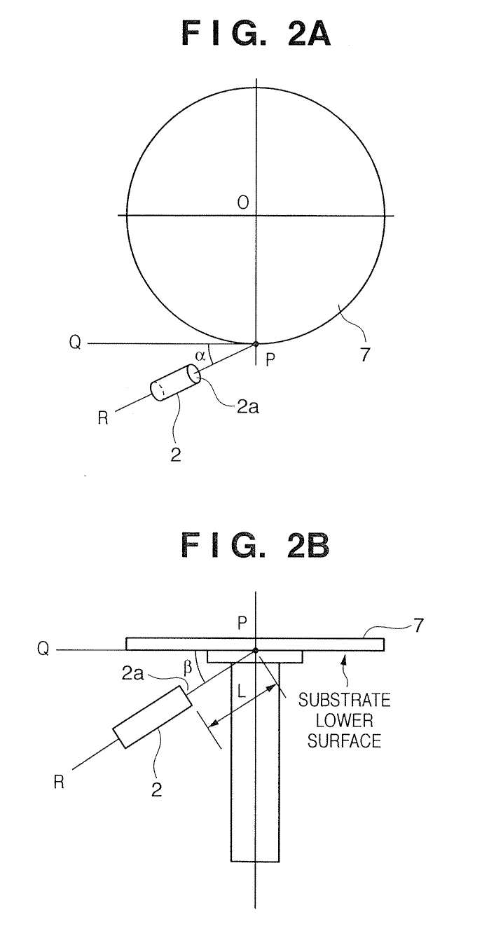

The positional relationship between the substrate to be processed and ion gun will be explained below with reference to FIGS. 2A and 2B.

As shown in FIGS. 2A and 2B, let O be the origin of rotation that is the center of the lower surface of the substrate 7, P be an arbitrary point on the outer periphery of the lower surface of the substrate 7, and Q be an arbitrary point on a tangent including P. Also, let R be an arbitrary point on a line segment that extends from the point P to the outside of the substrate 7 to make an angle α with a line segment PQ in a plane including the points O, P, and Q, and extends from the point P to the downside of the substrate 7 to make an angle β with the line segment PQ in a plane parallel to the perpendicular dropped to the substrate 7 and including the line segment PQ. The cylindrical ion gun 2 is set such that its central axis overlaps a line segment PR. By setting the ion gun 2 in a position where 0°<α<90° and 0°<β<180°, the lower surface edge and circumferential surface of the substrate 7 can be simultaneously irradiated with the ion beam. However, the angle α is preferably 45° or less because it is unfavorable to emit the ion beam to the thin film formed on the upper surface of the substrate 7.

The ion gun 2 is set in a position where a distance L between an ion beam emitting hole 2a and the lower surface of the substrate 7 is 10 to 500 mm. In this embodiment, both the angles α and β were 30°, and the distance L was 50 mm.

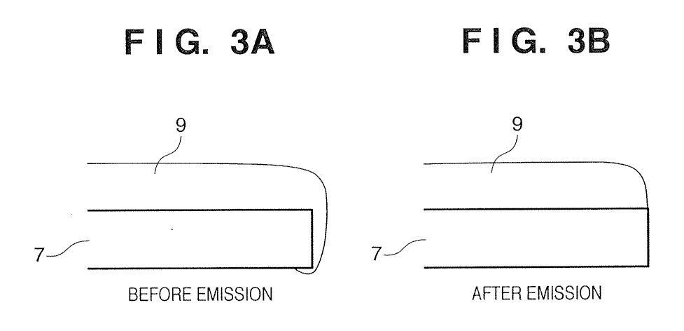

FIGS. 3A and 3B illustrate the states of the adhesion of a film to the lower surface edge and circumferential surface of the substrate to be processed before and after ion beam emission. In this embodiment as shown in FIGS. 3A and 3B, it was possible to remove the contaminant adhered to the range of 2 mm from the edge of the lower surface and the circumferential surface of the substrate 7 across the entire periphery of the substrate 7.

This embodiment is explained by taking, as an example, the arrangement in which the substrate rotating mechanism 3 rotates the substrate holder 4 holding the substrate 7, and the ion gun 2 emits the ion beam to the edge and circumferential surface of the rotating substrate 7 from its lower surface side. However, an arrangement applicable to the present invention is not limited to this arrangement. Instead of this arrangement, it is also possible to use an arrangement in which the ion gun 2 is moved along the periphery of the substrate 7 held and fixed on the substrate holder 4 while the ion gun 2 is emitting the ion beam to the edge and circumferential surface of the substrate 7 from its lower surface side. Furthermore, it is possible to combine the arrangement in which the substrate rotating mechanism 3 rotates the substrate holder 4 holding the substrate 7 with the arrangement in which the ion gun 2 is moved along the periphery of the substrate 7.

### Second Embodiment

In the positional relationship between the substrate 7 and ion gun 2 shown in FIGS. 2A and 2B, a film attached to the lower surface edge and circumferential surface of the substrate 7 can be removed as described above. However, the film (contaminant) removed by the ion beam may stick to the upper surface of the substrate 7.

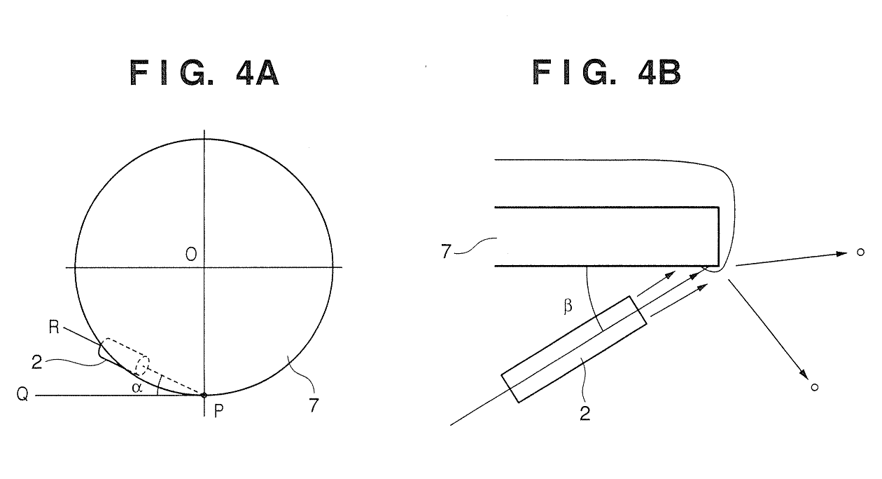

By contrast, in this embodiment, an ion gun 2 set such that the angle a satisfies −90°<α<0° as shown in FIG. 4A first removes only a contaminant on the lower surface edge of a substrate 7 to be processed. When the ion gun 2 set at the angle α as described above emits an ion beam to the lower surface edge of the substrate 7, the contaminant removed from the substrate 7 flies outside the substrate (FIG. 4B). This makes it possible to prevent the contaminant from adhering on the substrate 7 again.

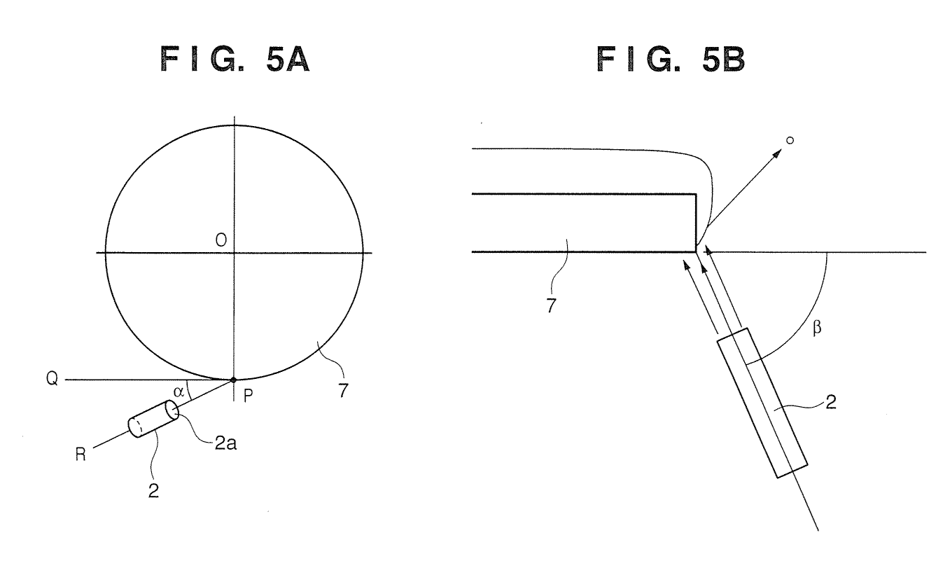

Then, the ion gun 2 set such that the angle a satisfies 0°<α<90° as shown in FIG. 5A removes the contaminant on the circumferential surface of the substrate 7. When the ion gun 2 set at the angle a as described above emits an ion beam to the circumferential surface of the substrate 7, it is possible to prevent the contaminant removed from the circumferential surface of the substrate 7 from sticking to the lower surface of the substrate 7 again (FIG. 5B).

To separately remove the contaminants on the lower surface edge and circumferential surface of the substrate 7 in the two steps as described above, a mechanism for changing the setting angle of the ion gun 2 may also be installed in a vacuum chamber 1 (FIG. 1).

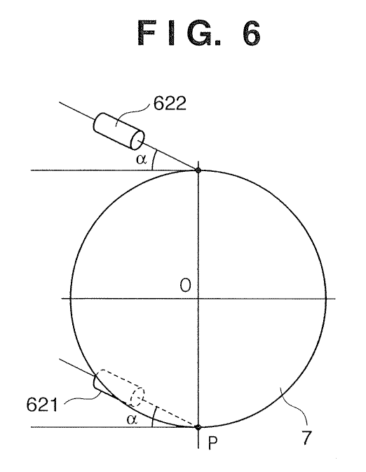

Alternatively, as shown in FIG. 6, two ion guns 621 and 622 different in ion beam incident angle to the substrate 7 may also be arranged. In the arrangement shown in FIG. 6, the setting angles α and β of the ion gun 621 for removing the contaminant on the lower surface edge of the substrate 7 are respectively −60° and 30°, and the setting angles α and β of the ion gun 622 for removing the contaminant on the circumferential surface of the substrate 7 are respectively 30° and 60°. Note that exhausting systems such as a gate valve and vacuum pump are preferably arranged along those extension lines of the ion guns 621 and 622 along which the contaminants fly. Consequently, the contaminants removed from the substrate 7 and floating in the vacuum chamber can be rapidly exhausted outside the vacuum chamber before they adhere to the substrate 7 again.

Note that an anti-adhesion plate (not shown) is installed in the vacuum chamber 1 of the processing chamber similarly to another film formation chamber. This anti-adhesion plate has a function of attracting contaminants, and is periodically replaced. The ion guns 621 and 622 may also be arranged so as to fly contaminants toward the anti-adhesion plate.

### Third Embodiment

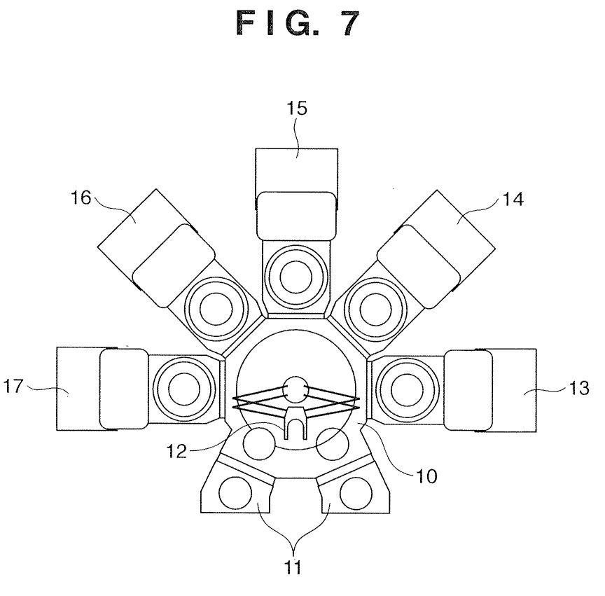

FIG. 7 is a view showing an outline of the arrangement of a flash memory insulating film formation apparatus as an example of the vacuum thin film formation processing apparatus of the present invention.

This insulating film formation apparatus shown in FIG. 7 has a vacuum transfer chamber 10 containing a vacuum transfer robot 12. The vacuum transfer chamber 10 is connected to a load lock chamber 11, substrate heating chamber 13, first PVD (sputtering) chamber 14, second PVD (sputtering) chamber 15, contaminant removing chamber 16, and substrate cooling chamber 17 via gate valves.

The operation of the insulating film formation apparatus shown in FIG. 7 will be explained below.

First, a substrate (silicon wafer) to be processed is set in the load lock chamber 11 for loading and unloading the substrate into and from the vacuum transfer chamber 10, and evacuation is performed until the pressure becomes 1×10⁻⁴ Pa or less. After that, the vacuum transfer robot 12 loads the substrate into the vacuum transfer chamber 10 in which the vacuum degree is maintained at 1×10⁻⁶ Pa or less, and transfers the substrate to a desired vacuum processing chamber.

In this embodiment, the substrate is first transferred to the substrate heating chamber 13 and heated to 400° C. The substrate is then transferred to the first PVD (sputtering) chamber 14, and a 15-nm thick Al₂O₃ film is formed on the substrate. Subsequently, the substrate is transferred to the second PVD (sputtering) chamber 15, and a 20-nm thick TiN film is formed on the substrate. After that, the substrate is transferred into the contaminant removing chamber 16, and the Al₂O₃ film and TiN film adhered to the lower surface edge and circumferential surface of the substrate are removed. Finally, the substrate is transferred into the substrate cooling chamber 17, and cooled to room temperature. After all the processes are completed, the substrate is returned to the load lock chamber 11, dried nitrogen gas is supplied until the pressure becomes the atmospheric pressure, and the substrate is unloaded from the load lock chamber 11.

In the insulating film formation apparatus of this embodiment, the vacuum degree of the vacuum processing chambers except for the contaminant removing chamber 16 is 1×10⁻⁶ Pa or less. Although the vacuum degree of the contaminant removing chamber 16 is 1×10⁻⁵ Pa or less, this vacuum degree is 0.04 to 0.1 Pa when the ion beam is emitted because Ar gas is supplied.

In this embodiment, the Al₂O₃ film and TiN film are formed by using magnetron sputtering. However, these films may also be formed by using, for example, laser abrasion, ion plating, vapor deposition, MBE, ALD, or CVD instead of magnetron sputtering. Also, in this embodiment, the contaminants sticking to the lower surface edge and circumferential surface of the substrate are removed in the contaminant removing chamber 16 after a plurality of film formation processes are performed on the substrate. However, the contaminant removing step in the contaminant removing chamber 16 may also be performed after each film formation process.

### Fourth Embodiment

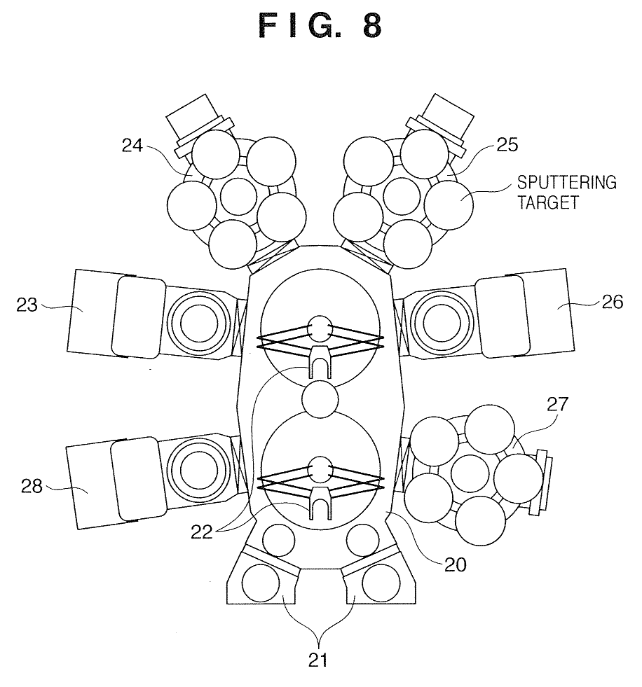

FIG. 8 is a view showing an outline of the arrangement of a magnetic random access memory (MRAM) magnetic tunnel junction formation apparatus as an example of the vacuum thin film formation processing apparatus of the present invention.

This magnetic tunnel junction formation apparatus shown in FIG. 8 has a vacuum transfer chamber 20 containing two vacuum transfer robots 22. The vacuum transfer chamber 20 is connected to three PVD (sputtering) chambers 24, 25, and 27, two load lock chambers 21, an oxidizing chamber 26, a substrate preprocessing chamber (reverse sputter etching chamber) 23, and a contaminant removing chamber 28 via gate valves. The PVD (sputtering) chambers 24, 25, and 27 each have five sputtering targets.

The operation of the magnetic tunnel junction formation apparatus shown in FIG. 8 will be explained below.

The vacuum transfer robot 22 loads a substrate to be processed from the load lock chamber 21 into the vacuum transfer chamber 20. First, the substrate is transferred into the substrate preprocessing chamber 23, and impurities attached to the surface of the substrate are physically removed by reverse sputter etching. Then, the substrate is transferred into the first PVD (sputtering) chamber 24, and a multilayered film including TaN (10 nm)/Ta (10 nm)/NiFe (2 nm)/PtMn (15 nm) is formed on the substrate.

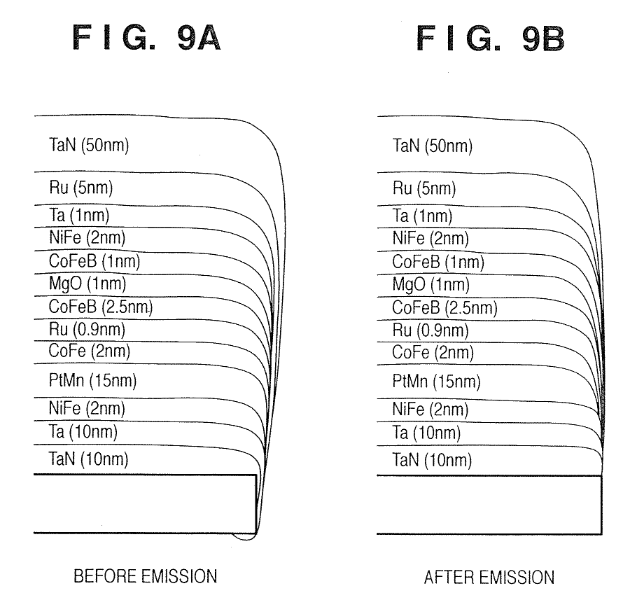

Subsequently, the substrate is transferred into the second PVD (sputtering) chamber 25, and a thin multilayered film including CoFe (2 nm)/Ru (0.9 nm)/CoFeB (2.5 nm)/Mg (1 nm) is formed on the substrate. The substrate is then transferred into the oxidizing chamber 26, and an MgO insulating film is formed by radically oxidizing the Mg (1 nm) layer. After that, the vacuum transfer robot 22 transfers the substrate into the third PVD (sputtering) chamber 27, and a multilayered film including CoFeB (1 nm)/NiFe (2 nm)/Ta (1 nm)/Ru (5 nm)/TaN (50 nm) is formed on the substrate. In this manner, a magnetic tunnel junction shown in FIG. 9A is formed on the entire surface of the substrate.

Finally, the substrate is transferred into the contaminant removing chamber 28, and the impurity elements forming the multilayered films adhered to the lower surface edge and circumferential surface of the substrate are removed. After that, the substrate is returned to the load lock chamber 21. In this way, it was possible to obtain the substrate having no contaminants sticking to the lower surface edge and circumferential surface (FIG. 9B).

In this embodiment, the contaminants sticking to the lower surface edge and circumferential surface of the substrate are removed in the contaminant removing chamber 28 after a plurality of film formation processes are performed. However, the contaminant removing step in the contaminant removing chamber 28 may also be performed after each film formation process.

### Fifth Embodiment

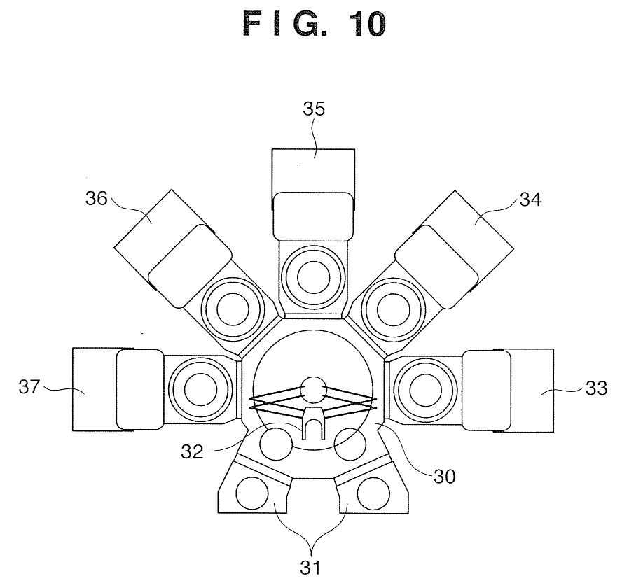

FIG. 10 is a view showing an outline of the arrangement of an apparatus as an example of the vacuum thin film formation processing apparatus of the present invention. This apparatus processes a substrate to be processed on which a patterned photoresist is formed on the magnetic tunnel junction formed in the fourth embodiment.

The apparatus shown in FIG. 10 has a vacuum transfer chamber 30 containing a vacuum transfer robot 32. The vacuum transfer chamber 30 is connected to two chemical etching (RIE) chambers 33 and 35, an ashing chamber 34 for performing physical etching, a chemical vapor deposition (thermal CVD) chamber 36, and a contaminant removing chamber 37 via gate valves.

A substrate to be processed on which the magnetic tunnel junction with a photoresist is formed is first transferred from a load lock chamber 31 into the first chemical etching (RIE) chamber 33 via the vacuum transfer chamber 30. In the first chemical etching (RIE) chamber 33, the photoresist applied on the substrate is used as a mask to etch the uppermost TaN layer by using a fluorine-based gas until the Ru layer is exposed. Then, the substrate is transferred into the ashing chamber 34, and the photoresist used as a mask in the preceding step is removed. After that, the substrate is transferred into the second chemical etching (RIE) chamber 35. In the second chemical etching (RIE) chamber 35, TaN left behind below the photoresist mask is used as a hard mask to etch the multilayered film from the Ru layer to the NiFe layer by using an alcohol-based gas until the Ta layer close to the surface of the substrate is exposed. Subsequently, the substrate is transferred into the chemical vapor deposition (thermal CVD) chamber 36, and an SiO₂ protective film is formed. Large amounts of contaminants have adhered to the lower surface edge and circumferential surface of the substrate through the series of processes up to this point.

Finally, the substrate is transferred into the contaminant removing chamber 37, and the lower surface edge and circumferential surface of the substrate are irradiated with an ion beam, thereby removing the contaminants.

### Sixth Embodiment

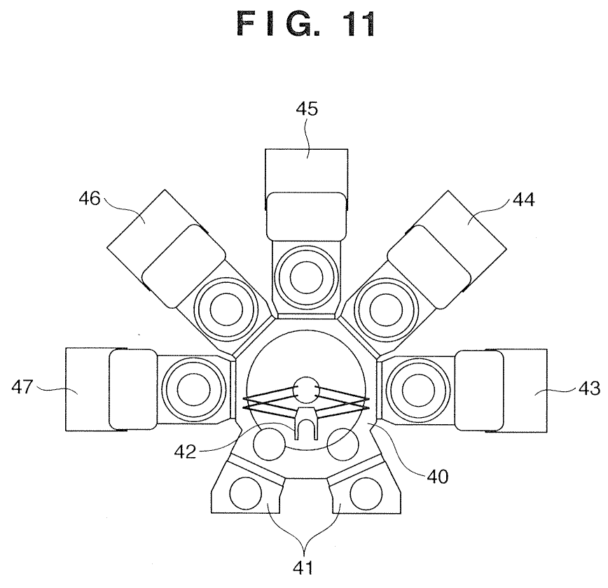

FIG. 11 is a view showing an outline of the arrangement of a phase change memory thin film formation apparatus as an example of the vacuum thin film formation processing apparatus of the present invention.

This thin film formation apparatus shown in FIG. 11 has a vacuum transfer chamber 40 containing a vacuum transfer robot 42. The vacuum transfer chamber 40 is connected to a load lock chamber 41, substrate heating chamber 43, substrate preprocessing chamber 44, first PVD (sputtering) chamber 45, second PVD (sputtering) chamber 46, and contaminant removing chamber 47 via gate valves.

The operation of the thin film formation apparatus shown in FIG. 11 will be explained below.

A substrate to be processed is loaded from the load lock chamber 41 into the vacuum transfer chamber 40. First, the substrate is transferred into the substrate heating chamber 43 and heated to 200° C. Then, the substrate is transferred into the substrate preprocessing chamber 44, and impurities sticking to the surface of the substrate are removed by reverse sputtering etching. After that, the substrate is transferred into the first PVD (sputtering) chamber 45, and a 60-nm thick film made of a chalcogenide-based phase change material such as GeSbTe is formed. Subsequently, the substrate is transferred into the second PVD (sputtering) chamber 46, and a 50-nm thick TiN film is formed. The substrate is then transferred into the contaminant removing chamber 47, and GeSbTe and TiN as contaminants adhered to the lower surface edge and circumferential surface of the substrate are removed. After all the processes are completed, the substrate is returned to the load lock chamber 41. Thus, after desired thin films are formed on the entire surface of a substrate to be processed, contaminants adhered to the lower surface edge and circumferential surface of the substrate can be removed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-203054, filed Aug. 3, 2007, which is hereby incorporated by reference herein in its entirety.

What is claimed is:

1. A contaminant removing method of removing a contaminant from a substrate to be processed, the method comprising a step of emitting, in a vacuum, a directional beam to at least one of a lower surface edge and circumferential surface of a substrate to be processed having a thin film formed on an upper surface thereof.

2. The method according to claim 1, wherein the beam is one of an ion beam, an electron beam, an atomic beam, a molecular beam, a cluster beam, and a laser beam.

3. The method according to claim 1, further comprising a step of fixing the substrate to be processed on a substrate holder by electrostatic force, and rotating the substrate to be processed together with the substrate holder, when emitting the beam to the lower surface edge and circumferential surface of the substrate to be processed.

4. A contaminant removing mechanism for removing a contaminant from a substrate to be processed, the mechanism comprising contaminant removing means for removing a contaminant adhered to at least one of a lower surface edge and circumferential surface of a substrate to be processed having a thin film formed on an upper surface thereof.

5. The mechanism according to claim 4, wherein said contaminant removing means is beam emitting means for emitting a directional beam to the lower surface edge and circumferential surface of the substrate to be processed.

6. The mechanism according to claim 5, wherein the beam is one of an ion beam, an electron beam, an atomic beam, a molecular beam, a cluster beam, and a laser beam.

7. The mechanism according to claim 5, wherein
said beam emitting means is ion beam emitting means for emitting an ion beam, and
the ion beam contains an ion of at least one element selected from the group consisting of He, N, O, Ne, Ar, Kr, and Xe as an ion species.

8. The mechanism according to claim 5, wherein
letting O be an origin of rotation which is a center of a lower surface of the substrate to be processed, P be an arbitrary point on an outer periphery of the lower surface of the substrate to be processed, Q be an arbitrary point on a tangent including P, and R be an arbitrary point on a line segment which extends from the point P to an outside of the substrate to be processed to make an angle α with a line segment PQ in a plane including the points O, P, and Q, and extends from the point P to a downside of the substrate to be processed to make an angle β with the line segment PQ in a plane parallel to a perpendicular dropped to the substrate to be processed and including the line segment PQ,
said beam emitting means is set in a position where 0°<α<90° and 0°<β<180°.

9. The mechanism according to claim 5, wherein
letting O be an origin of rotation which is a center of a lower surface of the substrate to be processed, P be an arbitrary point on an outer periphery of the lower surface of the substrate to be processed, Q be an arbitrary point on a tangent including P, and R be an arbitrary point on a line segment which extends from the point P to an outside of the substrate to be processed to make an angle α with a line segment PQ in a plane including the points O, P, and Q, and extends from the point P to a downside of the substrate to be processed to make an angle β with the line segment PQ in a plane parallel to a perpendicular dropped to the substrate to be processed and including the line segment PQ,
said beam emitting means is set in a position where −90°<α<0° and 0°<β<180°.

10. The mechanism according to claim 4, further comprising:
a substrate holder configured to hold and fix the substrate to be processed; and
rotating means for rotating said substrate holder.

11. A contaminant removing chamber comprising a contaminant removing mechanism defined in claim 4 in a vacuum chamber.

12. A vacuum thin film formation processing apparatus comprising:
a contaminant removing chamber cited in claim 11; and
at least one vacuum processing chamber selected from the group consisting of a physical vapor deposition (PVD) chamber, a chemical vapor deposition (CVD) chamber, a physical etching chamber, a chemical etching chamber, a substrate heating chamber, a substrate cooling chamber, an oxidizing chamber, a reducing chamber, and an ashing chamber.

13. The apparatus according to claim 12, wherein said contaminant removing chamber and said at least one vacuum processing chamber are connected via a vacuum transfer chamber.
